(19) United States
(12) Patent Application Publication
(10) Pub. No.: US 2025/0333623 A1
(43) Pub. Date: Oct. 30, 2025

(54) OPTICAL MEMBER AND DISPLAY APPARATUS COMPRISING OPTICAL MEMBER

(71) Applicant: SAMSUNG SDI CO., LTD., Yongin-si (KR)

(72) Inventors: Irina NAM, Yongin-si (KR); Tae Ji KIM, Yongin-si (KR); Won KIM, Yongin-si (KR); Dong Heon YUN, Yongin-si (KR); Il Jin KIM, Yongin-si (KR)

(21) Appl. No.: 19/194,713

(22) Filed: Apr. 30, 2025

(30) Foreign Application Priority Data
Apr. 30, 2024 (KR) 10-2024-0057505

(51) Int. Cl. C09J 7/29; C09B 47/04; C09B 57/00; C09B 67/20; G02B 5/22

(52) U.S. Cl. CPC C09J 7/29; C09B 47/04; C09B 57/00; C09B 67/0064; G02B 5/223; C09J 2301/162; C09J 2301/41; C09J 2301/414

(57) ABSTRACT

The present disclosure provides an optical member and an optical display apparatus including the optical member. The optical member includes: an adhesive layer; a transmittance control layer formed on an upper surface of the adhesive layer; and a base film formed on an upper surface of the transmittance control layer. The transmittance control layer includes a (meth)acrylic copolymer and a dye mixture. The dye mixture includes a first dye having a maximum absorption wavelength from 400 nm to 440 nm, a second dye having a maximum absorption wavelength from 480 nm to 520 nm, a third dye having a maximum absorption wavelength from 570 nm to 610 nm, and a fourth dye having a maximum absorption wavelength from 650 to 700 nm. The (meth)acrylic copolymer includes a cycloaliphatic group-containing (meth)acrylic copolymer having a glass transition temperature from 50° C. to 150° C. The cycloaliphatic group-containing (meth)acrylic copolymer comprises from 35 wt % to 70 wt % of a cycloaliphatic group-containing (meth)acrylic monomer.

### CROSS-REFERENCE TO RELATED APPLICATION

The present application claims priority and the benefit of Korean Patent Application No. 10-2024-0057505, filed on Apr. 30, 2024 in the Korean Intellectual Property Office, the entire disclosure of which is incorporated herein by reference.

### FIELD

The present disclosure relates to an optical member and a display apparatus including the optical member.

### DESCRIPTION OF THE RELATED ART

Light emitting display apparatuses, including organic light emitting display apparatuses and the like, may be free from a polarizing plate. However, such a light emitting display apparatus can have poor screen quality due to total reflection of external light at a surface of a panel contained therein. Therefore, it is common for light emitting display apparatuses to have a polarizing plate on an upper surface of the panel. The polarizing plate typically includes a polarizer and a retardation film. Also, the polarizing plate mat contain a UV absorber. The polarizing plate also serves to prevent external light from damaging a light emitting device.

Along with the recent trend towards reducing thickness of optical display apparatuses, development of an optical display apparatus free from a polarizing plate (as known as a “pol-less” optical display apparatus) has been ongoing. Still, the light emitting device in such a pol-less display apparatus is directly exposed to external light and thus can be easily damaged by external light.

The background technique of the present disclosure is disclosed in Japanese Patent Laid-open Publication No. 2015-010192.

### SUMMARY

Embodiments of the present disclosure provides an optical member that has a low light transmittance variation at a wavelength from 400 nm to 600 nm, even after long-term exposure to UV light, and even under repeated temperature changes between room temperature and high temperature.

Embodiments of the present disclosure provides an optical member that provides a reflectance of 6.5% to 9.5%, as measured on a panel for display apparatuses.

Embodiments of the present disclosure relate to an optical member.

In an embodiment, the optical member includes: an adhesive layer; a transmittance control layer formed on an upper surface of the adhesive layer; and a base film formed on an upper surface of the transmittance control layer. The transmittance control layer includes a (meth)acrylic copolymer and a dye mixture. The dye mixture includes a first dye having a maximum absorption wavelength from 400 nm to 440 nm, a second dye having a maximum absorption wavelength from 480 nm to 520 nm, a third dye having a maximum absorption wavelength from 570 nm to 610 nm, and a fourth dye having a maximum absorption wavelength from 650 to 700 nm. The (meth)acrylic copolymer includes a cycloaliphatic group-containing (meth)acrylic copolymer having a glass transition temperature from 50° C. to 150° C. The cycloaliphatic group-containing (meth)acrylic copolymer comprises from 35 wt % to 70 wt % of a cycloaliphatic group-containing (meth)acrylic monomer.

Embodiments of the present disclosure relate to an optical display apparatus.

In an embodiment, the optical display apparatus includes the optical member.

Embodiments of the present disclosure provides an optical member that has a low light transmittance variation at a wavelength from 400 nm to 600 nm, even after long-term exposure to UV light, and even under repeattemperature fluctuations between room temperature and high temperature, thereby improving reliability of a display apparatus.

Embodiments of the present disclosure provide an optical member having a reflectance of 6.5% to 9.5%, as measured on a panel for display apparatuses, thereby improving screen quality.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is a cross-sectional view of an optical member, according to an embodiment of the present disclosure.

FIG. 2 is a graph depicting light transmittance of an optical member of Example 1 as a function of wavelength, according to an embodiment of the present disclosure.

FIG. 3 is a graph depicting light transmittance of an optical member of Comparative Example 1 as a function of wavelength, according to an embodiment of the present disclosure.

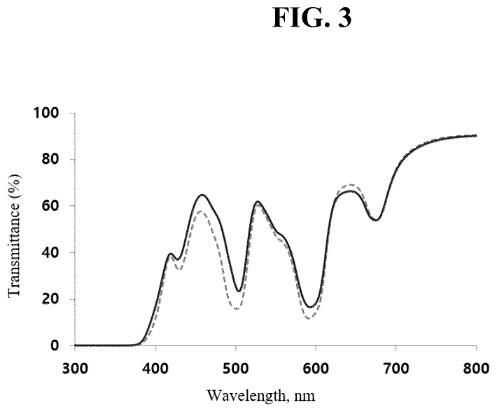

In FIG. 2 and FIG. 3, the solid line indicates initial light transmittance, and the dotted line indicates light transmittance after solar testing.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure.

Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

As used herein, a “homopolymer glass transition temperature” may refer to a glass transition temperature (Tg) measured on a homopolymer of a target monomer using a differential scanning calorimeter (Discovery, TA Instruments Inc.). Specifically, the homopolymer of the target monomer is heated to 180° C. at a heating rate of 20° C./min, cooled gradually to −100° C., and heated to 100° C. at a heating rate of 10° C./min to obtain data on an endothermic transition curve, followed by determining the glass transition temperature by an inflection point of the endothermic transition curve.

As used herein, a “light transmittance” refers to total luminous transmittance.

As used herein, a “light emitting device” includes an organic or organic/inorganic hybrid light emitting device and may refer to a device including a light emitting diode (LED), an organic light emitting diode (OLED), a quantum dot light emitting diode (QLED), a light emitting material, such as a phosphor, or the like.

As used herein, a “(meth)acryl” refers to acryl and/or methacryl.

As used herein, a “maximum absorption wavelength” refers to a wavelength at which a maximum absorbance appears in measurement of absorbance of a dye solution in which a dye is dissolved at a concentration of 10 ppm in methyl ethyl ketone. The absorbance may be measured by a typical method known to those skilled in the art.

As used herein, to represent a specific numerical range, the expression “X to Y” means “greater than or equal to X and less than or equal to Y (X≤ and ≤Y)”.

Embodiments of the present disclosure provide an optical member. The optical member may be used in an optical display apparatus in the absence of a polarizing plate (which may include a polarizer). In an embodiment, the optical display apparatus can be a light emitting display apparatus in the absence of a polarizing plate.

The optical member can have a low light transmittance variation, even after long-term exposure to UV light, and even under repeat temperature fluctuations between room temperature and elevated temperature. In an embodiment, the optical member can be configured to prevent external light from damaging a light emitting device, even after long-term exposure to UV light and even under repeat temperature fluctuations between room temperature and elevated temperature.

In an embodiment, the optical member can have a light transmittance variation (ΔT(λ)) of equal to or less than 3%, as calculated according to Equation 1. This way, the optical member can be configured to reduce damage to a light emitting device, even after long-term exposure to UV light, thereby improving lifespan of a light emitting display apparatus.

$$Δ T ( λ ) = \vert {T}_{2} ( λ ) - {T}_{1} ( λ ) \vert , \qquad [ Equation 1 ]$$

where T₁(λ) is a light transmittance (unit: %) of the optical member at a wavelength λ(nm) in the range from 400 nm to 585 nm and T₂(λ) is a light transmittance (unit: %) of the optical member at a wavelength, (nm) in the range from 400 nm to 585 nm, measured after a total of, for example, 21 cycles of light irradiation, wherein one cycle is defined as irradiating the optical member with a 340 nm UV light at a fluence of 0.35 W/m² while leaving the optical member at 25° C. for 4 hours subsequently at 63° C. for 8 hours.

In an embodiment, ΔT(λ) calculated according to Equation 1 may be a value measured at a wavelength of 400 nm.

In an embodiment, ΔT(λ) calculated according to Equation 1 may be a value measured at a wavelength of 490 nm.

In an embodiment, ΔT(λ) calculated according to Equation 1 may be a value measured at a wavelength of 585 nm.

In an embodiment, the optical member can have a light transmittance variation (ΔT(λ)) of equal to or less than 3%, for example, 1% to 2.9% or 2.15% to 2.84%, as calculated according to Equation 1.

In an embodiment, T₁ in Equation 1 may be equal to or less than 30%, for example, 10% to 27%.

In an embodiment, T₂ in Equation 1 may be equal to or less than 30%, for example, 10% to 27%.

The optical member can include: an adhesive layer; a transmittance control layer formed on an upper surface of the adhesive layer; and a base film formed on an upper surface of the transmittance control layer. The transmittance control layer includes a (meth)acrylic copolymer and a dye mixture. The dye mixture includes a first dye having a maximum absorption wavelength from 400 nm to 440 nm, a second dye having a maximum absorption wavelength from 480 nm to 520 nm, a third dye having a maximum absorption wavelength from 570 nm to 610 nm, and a fourth dye having a maximum absorption wavelength from 650 to 700 nm. The (meth)acrylic copolymer includes a cycloaliphatic group-containing (meth)acrylic copolymer having a glass transition temperature from 50° C. to 150° C. The cycloaliphatic group-containing (meth)acrylic copolymer comprises from 35 wt % to 70 wt % of a cycloaliphatic group-containing (meth)acrylic monomer.

The optical member may further include a release film applied on the lower surface of the adhesive layer to protect the adhesive layer.

### Adhesive Layer

The adhesive layer can be configured to adhesively bond the optical member to a panel for optical display apparatuses. The adhesive layer can include a cured product of a composition.

In an embodiment, the cured product may be a thermally cured product of the composition.

The composition can include a UV absorber and a (meth)acrylic copolymer.

The UV absorber can be configured to absorb light in the wavelength range from 360 nm to 410 nm. The UV absorber can be configured to significantly prevent external light from damaging a light emitting device via absorbing light in the wavelength range from 360 nm to 410 nm.

In an embodiment, the UV absorber may be an indole UV absorber.

The indole UV absorber can have a low light transmittance not only at a wavelength from 360 nm to 410 nm or from 400 nm to 405 nm, in comparison with other types of UV absorbers, and thus can be configured to sufficiently suppress damage to a light emitting device. In an embodiment, the optical member including the indole UV absorber may have a light transmittance of equal to or less than 5% at a wavelength of 405 nm.

In an embodiment, the indole UV absorber may include a compound represented by Formula 1:

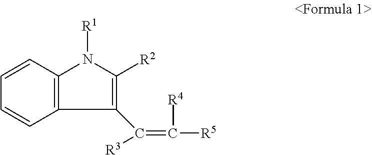

where R¹ is hydrogen or a substituted or unsubstituted C₁ to C₁₀ alkyl group,
R² is hydrogen or a substituted or unsubstituted C₆ to C₂₀ aryl group,
R³ is hydrogen or a substituted or unsubstituted C₁ to C₁₀ alkyl group,
R⁴ is hydrogen, a cyano group (—CN), or a substituted or unsubstituted C₁ to C₁₀ alkyl group, and
R⁵ is a cyano group or —(C═O)—O—R⁶ (R⁶ being a substituted or unsubstituted C₁ to C₁₀ alkyl group or a substituted or unsubstituted C₆ to C₂₀ aryl group).

In an embodiment, R¹ may be a C₁ to C₅ alkyl group, for example, a methyl group, R² may be a C₆ to C₁₀ aryl group, for example, a phenyl group, R³ may be hydrogen or a C₁ to C₅ alkyl group, for example, hydrogen, R⁴ may be a cyano group, and R⁵ may be a cyano group or —(C═O)—O—R⁶ (R⁶ being a substituted or unsubstituted C₁ to C₅ alkyl group). In an embodiment, the compound represented by Formula 1 may include a compound represented by Formula 1-1 or a compound represented by Formula 1-2:

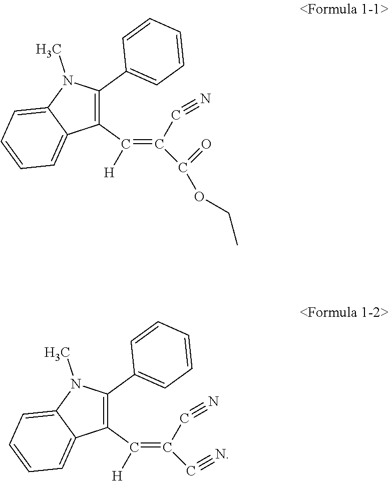 [SMILES: CCOC(=O)/C(C#N)=C/c1c(-c2ccccc2)n(C)c2ccccc12 ; Cn1c(-c2ccccc2)c(C=C(C#N)C#N)c2ccccc21]

The compound represented by Formula 1 may have a melting point of equal to or greater than 100° C., for example, 140° C. to 220° C., and can exist in solid phase at room temperature. The compound represented by Formula 1 may be synthesized by a method known in the art, or may be a commercially available product.

The compound represented by Formula 1 may have an absorbance of equal to or greater than 0.8 absorbance units (AU), for example, 0.8 AU to 1.0 AU, at a wavelength of 390 nm under the following conditions: chloroform concentration: 10 mg/L; and path length: 1 cm, and may have a maximum absorption wavelength of greater than 390 nm, for example, greater than 390 nm and equal to or less than 400 nm, or greater than 390 nm and less than 400 nm. In these ranges, the compound represented by Formula 1 can be configured to reduce light transmittance of the optical member via sufficient light absorption at a wavelength of equal to or less than 420 nm, for example, 400 nm to 420 nm, among external light incident on the optical member, thereby improving stability of a light emitting device against external light. As used herein, “maximum absorption wavelength” refers to a wavelength at which a maximum absorption peak appears, that is, a wavelength corresponding to a maximum absorbance in an absorbance curve as a function of wavelength. The absorbance may be measured by a method known in the art.

The UV absorber may be present in an amount from 0.1 wt % to 3 wt % relative to the adhesive layer. This way, the UV absorber can be configured to sufficiently suppress damage to a light emitting device without reducing light transmittance of the optical member, for example, by having excess UV absorber. In an embodiment, the UV absorber may be present in an amount from 0.3 wt % to 1.5 wt % relative to the adhesive layer.

The UV absorber may be present in an amount from 0.3 parts by weight to 3 parts by weight, for example, from 0.3 parts by weight to 1.5 parts by weight, relative to 100 parts by weight of the (meth)acrylic copolymer. This way, the UV absorber can be configured to ensure reduced light transmittance of the optical member at a wavelength of 380 nm without excessively increasing color value b*, for example, by having excess UV absorber.

In an embodiment, the adhesive layer may be a pressure sensitive adhesive layer.

The (meth)acrylic copolymer may be a non-carboxylic acid-based copolymer that does not contain a carboxylic acid group. Use of carboxylic acid group-containing (meth)acrylic copolymers may result in the optical member being less durable when the optical member is adhesively bonded to a panel for optical display apparatuses.

The (meth)acrylic copolymer may be a copolymer of a monomer mixture including an alkyl group-containing (meth)acrylic monomer having a homopolymer glass transition temperature equal to or less than −40° C., a monomer having a homopolymer glass transition temperature equal to or greater than 15° C., and a hydroxyl group-containing (meth)acrylic monomer.

In an embodiment, the alkyl group-containing (meth)acrylic monomer having a homopolymer glass transition temperature equal to or less than −40°, the monomer having a homopolymer glass transition temperature equal to or greater than 15° C., and the hydroxyl group-containing (meth)acrylic monomer may be present, in total, in an amount of equal to or greater than 99 mol %, for example, 100 mol %, in the monomer mixture. This way, the (meth)acrylic copolymer can be configured to achieve the desired effects of the optical member described above.

The alkyl group-containing (meth)acrylic monomer having a homopolymer glass transition temperature equal to or less than −40° C. can be configured to facilitate increase in peel strength of the adhesive layer and formation of a matrix of the adhesive layer. In an embodiment, the alkyl group-containing (meth)acrylic monomer may have a homopolymer glass transition temperature from −80° C. to −40° C. In an embodiment, the alkyl group-containing (meth)acrylic monomer may have a homopolymer glass transition temperature from −80° C. to −50° C., for example, from −80° C. to −60° C. This way, the alkyl group-containing (meth)acrylic monomer can be configured to acheive the desired effects of the optical member described above, in combination with the (meth)acrylic monomer having a greater homopolymer glass transition temperature.

The alkyl group-containing (meth)acrylic monomer may include a (meth)acrylic acid ester having a linear or branched C₁ to C₈ alkyl group at an ester site thereof. Here, the carbon number refers to the number of carbon atoms forming a main chain of the alkyl group. In an embodiment, the alkyl group has a carbon number of 6 to 8.

In an embodiment, the alkyl group-containing (meth)acrylic monomer may include one or more of n-butyl (meth)acrylate, pentyl (meth)acrylate, hexyl (meth)acrylate, 2-ethylhexyl (meth)acrylate, heptyl (meth)acrylate, octyl (meth)acrylate, and isooctyl (meth)acrylate, without being limited thereto. These compounds may be used alone or as a mixture thereof. In an embodiment, the alkyl group-containing (meth)acrylic monomer having a homopolymer glass transition temperature of equal to or less than −40° C. is 2-ethylhexyl (meth)acrylate.

The alkyl group-containing (meth)acrylic monomer may be present in an amount from 65 mol % to 90 mol %, for example, from 70 mol % to 90 mol % or from 70 mol % to 85 mol %, relative to the monomer mixture. This way, the alkyl group-containing (meth)acrylic monomer can be configured to enhance peel strength of the adhesive layer.

The monomer having a homopolymer glass transition temperature equal to or greater than 15° C. may be essential to produce the desired effects of the optical member.

Monomers having a homopolymer glass transition temperature of less than 15° C. can result in undesirable optical properties, for example, during solar testing. For example, such monomers may have a homopolymer glass transition temperature from −30° C. to −10° C.

In an embodiment, the monomer having a homopolymer glass transition temperature equal to or greater than 15° C. may have a homopolymer glass transition temperature from 15° C. to 260° C., for example, from 15° C. to 210° C. This way, the monomer can be configured to achieve the desired effects of the optical member in combination with the (meth)acrylic monomer having a less homopolymer glass transition temperature.

The monomer having a homopolymer glass transition temperature equal to or greater than 15° C. may include at least one of a (meth)acrylic acid ester having an alkyl group or a cycloaliphatic group at an ester site thereof or a maleimide having a cycloaliphatic group or an aromatic group.

In an embodiment, the (meth)acrylic acid ester having an alkyl group at an ester site thereof is tert-butyl (meth)acrylate or vinyl acetate. In an embodiment, the (meth)acrylic acid ester having a cycloaliphatic group at an ester site thereof can include one or more of isobornyl (meth)acrylate, cyclohexyl (meth)acrylate, and dicyclopentadienyl (meth)acrylate. In an embodiment, the maleimide having a cycloaliphatic group is N-cyclohexyl maleimide or the like. In an embodiment, the maleimide having an aromatic group is phenyl maleimide or the like.

The monomer having a homopolymer glass transition temperature equal to or greater than 15° C. may be present in an amount from 5 mol % to 40 mol %, for example, from 10 mol % to 30 mol % or from 15 mol % to 30 mol %, relative to the monomer mixture. This way, the monomer can be configured to ensure that the optical member satisfies the requirements of Equation 1 without negatively affecting the peel strength of the adhesive layer.

The hydroxyl group-containing (meth)acrylic monomer can be configured to enhance peel strength of the adhesive layer via reacting with a curing agent. The hydroxyl group-containing (meth)acrylic monomer is a hydroxyl group-containing (meth)acrylic acid ester and may include a (meth)acrylic acid ester having a C₁ to C₂₀ alkyl group containing at least one hydroxyl group at an ester site thereof. In an embodiment, the hydroxyl group-containing (meth)acrylic monomer may one or more of 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, and 1-chloro-2-hydroxypropyl (meth)acrylate. These compounds may be used alone or as a mixture thereof.

The hydroxyl group-containing (meth)acrylic monomer may be present in an amount from 0.1 mol % to 5 mol %, for example, from 0.5 mol % to 3 mol % or from 0.5 mol % to 1 mol %, relative to the monomer mixture. This way, the hydroxyl group-containing (meth)acrylic monomer can be configured to ensure that the optical member satisfies the requirements of Equation 1 without reducing mechanical strength of the adhesive layer.

The monomer mixture may be in the absence of a long-chain alkyl group-containing (meth)acrylic acid ester. Use of the long-chain alkyl group-containing (meth)acrylic acid ester in the monomer mixture can cause inadequate cohesion and adhesion properties of the adhesive layer. As used herein, the “long-chain alkyl group-containing (meth)acrylic acid ester” may refer to a (meth)acrylic acid ester having a C₁₀ to C₂₅ alkyl group. Here, the carbon number refers to the number of carbon atoms forming a main chain of the long-chain alkyl group.

The (meth)acrylic copolymer may have a glass transition temperature from −60° C. to −10° C., for example, from −60° C. to −30° C., from −60° C. to −40° C., or from −60° C. to −50° C. This way, the (meth)acrylic copolymer can be configured to achieve the desired effects of the optical member.

The (meth)acrylic copolymer may have a weight average molecular weight from 500,000 g/mol to 1,500,000 g/mol, for example, from 500,000 g/mol to 1,000,000 g/mol or from 600,000 g/mol to 1,000,000 g/mol. This way, the (meth)acrylic copolymer can be configured to achieve the desired effects of the optical member.

The (meth)acrylic copolymer may be prepared by polymerizing the monomer mixture using a polymerization method known in the art. In an embodiment, the (meth)acrylic copolymer may be prepared by adding an initiator to the monomer mixture, followed by conducting a typical copolymer polymerization process, for example, suspension polymerization, emulsion polymerization, solution polymerization, or the like. In an embodiment, polymerization of the monomer mixture may be carried out at a temperature from 65° C. to 70° C. for 6 to 8 hours. The initiator may be a initiator known in the art, including but not limited to, an azo polymerization initiator and a peroxide polymerization initiator, such as benzoyl peroxide or acetyl peroxide.

The composition may further include a curing agent.

The curing agent can be configured to provide peel strength via reacting with the (meth)acrylic copolymer.

The curing agent may include a thermal curing agent. The thermal curing agent can be configured to facilitate formation of the adhesive layer from the adhesive layer composition including the UV absorber.

The curing agent may be present in an amount from 0.1 parts by weight to 5 parts by weight, for example, from 0.05 parts by weight to 2.5 parts by weight, relative to 100 parts by weight of the (meth)acrylic copolymer. This way, the curing agent can be configured to ensure adhesion of the adhesive layer by inducing crosslinking of the adhesive layer composition without sacrificing transparency due to an excess of the curing agent.

The thermal curing agent may include one or more of an isocyanate curing agent, a metal chelate curing agent, an epoxy curing agent, an aziridine curing agent, an amine curing agent, and a thermal polymerization initiator. In an embodiment, the thermal curing agent may include at least one of an isocyanate curing agent or a metal chelate curing agent. These curing agents may be used alone or in combination thereof.

The isocyanate curing agent can be a polyfunctional, for example, bifunctional to hexafunctional, isocyanate curing agent, and may include one or more of xylene diisocyanate (XDI) such as m-xylene diisocyanate and the like, methylene bis(phenyl isocyanate) (MDI) such as 4,4′-methylenebis(phenyl isocyanate) and the like, naphthalene diisocyanate, tolylene diisocyanate, hexamethylene diisocyanate, isophorone diisocyanate, and an adduct thereof.

The metal chelate curing agent may include a coordination compound of a polyvalent metal such as aluminum. In an embodiment, the metal chelate curing agent may include an aluminum chelate compound, such as aluminum tris(ethylacetoacetate), aluminum ethylacetoacetate diisopropylate, aluminum tris(acetylacetonate), and the like.

The adhesive layer composition may include a solvent. The solvent can be configured to improve coatability of the adhesive layer composition while preventing self-curing of the adhesive layer composition. The solvent may include a typical solvent known in the art. In an embodiment, the solvent may include one or more of methyl ethyl ketone, ethyl acetate, and toluene.

The adhesive layer composition may further include one or more of a silane coupling agent, a reworking agent, a curing catalyst, and an antistatic agent.

The silane coupling agent can be configured to provide better adhesion of the adhesive layer to an adherend such as glass. The silane coupling agent may include a typical silane coupling agent known in the art. In an embodiment, the silane coupling agent may include one or more of: a silicone compound having an epoxy structure, such as 3-glycidoxypropyltrimethoxysilane, 3-glycidoxypropylmethyldimethoxysilane, and 2-(3,4-epoxycyclohexyl)ethyltrimethoxysilane; a polymerizable unsaturated group-containing silicone compound, such as vinyltrimethoxysilane, vinyltriethoxysilane, and (meth)acryloxypropyltrimethoxysilane; an amino group-containing silicone compound, such as 3-aminopropyltrimethoxysilane, N-(2-aminoethyl)-3-aminopropyltrimethoxysilane, and N-(2-aminoethyl)-3-aminopropylmethyldimethoxysilane; and 3-chloropropyltrimethoxysilane, without being limited thereto. The silane coupling agent may be present in an amount from 0.001 parts by weight to 5 parts by weight, for example, from 0.001 parts by weight to 3 parts by weight, relative to 100 parts by weight of the (meth)acrylic copolymer. This way, the silane coupling agent can be configured to ensure good durability of the adhesive layer while reducing changes in composition and properties of the adhesive layer over time.

The reworking agent can be configured to improve reworkability of the adhesive layer and may include a polysiloxane oligomer or a mixture including the polysiloxane oligomer. The reworking agent may be present in an amount from 0.001 parts by weight to 5 parts by weight, for example, from 0.005 parts by weight to 1 part by weight, relative to 100 parts by weight of the (meth)acrylic copolymer. This way, the reworking agent can improve reworkability of the adhesive layer without negatively affecting the properties of the adhesive layer.

The antistatic agent can be configured to inhibit generation of static electricity during reworking of the adhesive layer and may include a typical antistatic agent known in the art. The antistatic agent may be present in an amount from 0.001 parts by weight to 5 parts by weight, for example, from 0.1 parts by weight to 5 parts by weight, relative to 100 parts by weight of the (meth)acrylic copolymer. This way, the antistatic agent can provide antistatic properties without affecting the properties of the adhesive layer.

The curing catalyst may include one or more of: a boron compound, for example, a boron trifluoride complex, specifically an etherate of boron trifluoride, a tetrahydrofuran complex of boron trifluoride (BF₃-THF), or an aniline complex of boron trifluoride (BF₃-aniline), for example, BF₃·O(CH₃)₂ (boron trifluoride dimethyl etherate) or BF₃—O(C₂H₅)₂ (boron trifluoride diethyl etherate); a phosphine compound, for example, triphenylphosphine, tributylphosphine, tri(p-methylphenyl)phosphine, tri(nonylphenyl)phosphine, triphenylphosphine/triphenylborate, tetraphenylborate, and the like; a secondary amine or tertiary amine compound, for example, an α-tertiary amine compound (for example, KH-30, Kukdo Chemical Co., Ltd.), such as triethylamine, benzydiethylamine, or benzydimethylamine; an imidazole compound, for example, 2-methylimidazole, 2-phenylimidazole, 2-phenyl-4-methylimidazole, and the like; or a sulfonic acid compound, for example, paratoluene sulfonic acid, dodecyl benzene sulfonic acid, naphthalene sulfonic acid, naphthalene disulfonic acid, methane sulfonic acid, methane disulfonic acid, phenol sulfonic acid, and the like. The curing catalyst may be present in an amount from 0.01 to 5 parts by weight, for example, from 0.05 to 2 parts by weight, relative to 100 parts by weight of the (meth)acrylic copolymer. This way, the curing catalyst can be configured to reduce the time required to complete curing.

The adhesive layer composition may further include additives known in the art. The additives may include an antioxidant, an adhesion imparting resin, a plasticizer, and the like. The additives may be present in an amount from 0.001 parts by weight to 5 parts by weight, for example, from 0.01 parts by weight to 1 part by weight, relative to 100 parts by weight of the (meth)acrylic copolymer. This way, the additives can be configured to provide intended effects without negatively affecting the properties of the adhesive layer.

The adhesive layer composition may have a viscosity from 1,000 centipoise (cP) to 4,000 cP at 25° C. This way, the adhesive layer composition can be configured to allow easy adjustment of the thickness of the adhesive layer, ensure that the adhesive layer is free from stains, and ensure an even coating surface.

The adhesive layer may have a thickness of equal to or less than 100 μm, for example, from 5 μm to 50 μm. This way, the adhesive layer can be used in an optical display apparatus.

The adhesive layer may be formed by coating the adhesive layer composition until reaching a predetermined thickness, drying the coated composition, and aging the dried composition in a constant temperature and humidity chamber at a temperature from 25° C. to 35° C. and a relative humidity from 30% to 60%, without being limited thereto.

### Transmittance Control Layer

The transmittance control layer may be formed between the adhesive layer and the base film and is configured to provide color conversion. In an embodiment, the transmittance control layer includes a dye mixture including a first dye having a maximum absorption wavelength from 400 nm to 440 nm, a second dye having a maximum absorption wavelength from 480 nm to 520 nm, a third dye having a maximum absorption wavelength from 570 nm to 610 nm, and a fourth dye having a maximum absorption wavelength from 650 nm to 700 nm.

The first dye has a maximum absorption wavelength from 400 nm to 440 nm and can be configured to reduce reflectance and improve screen quality. In an embodiment, the first dye may have a maximum absorption wavelength from 420 nm to 440 nm, for example 400, 405, 410, 415, 420, 425, 430, 435, 440 nm.

The first dye may be a dialkoxy group-substituted porphyrin dye. In an embodiment, the first dye may be a dye represented by Formula 2:

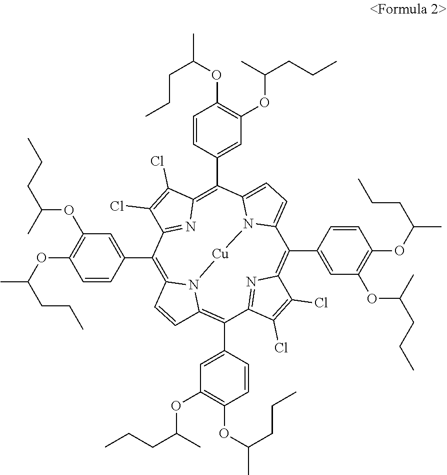

The first dye may be present in an amount from 0.001 wt % to 5 wt %, for example, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5 wt %, from 1 wt % to 5 wt % or from 0.1 wt % to 2%, relative to the transmittance control layer. This way, the first dye can be configured to increase transmittance and reduce reflectance in combination with the other dyes in the transmittance control layer.

The second dye can have a maximum absorption wavelength from 480 nm to 520 nm and can be configured to reduce reflectance and improve screen quality. In an embodiment, the second dye may have a maximum absorption wavelength from 490 nm to 520 nm, for example 480, 485, 490, 495, 500, 505, 510, 515, 520 nm.

The second dye may be a BODIPY (4,4-difluoro-4-bora-3a,4a-diaza-s-indacene) dye or a mixture including the BODIPY dye. For example, the BODIPY dye may include a dye represented by Formula 3:

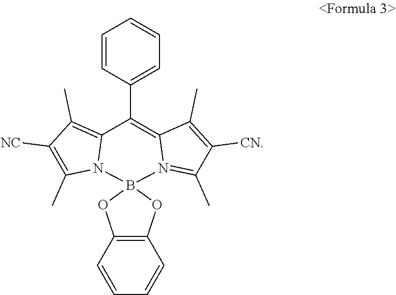

The second dye may be present in an amount from 0.001 wt % to 5 wt %, for example, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5 wt %, from 0.1 wt % to 5 wt % or from 0.1 wt % to 2 wt %, relative to the transmittance control layer. This way, the second dye can be configured to increase transmittance and reduce reflectance in combination with the other dyes in the transmittance control layer.

The third dye can have a maximum absorption wavelength from 570 nm to 610 nm, for example 570, 575, 580, 585, 590, 595, 600, 605, 610 nm.

The third dye may be a tetraazaporphyrin dye or a mixture including the tetraazaporphyrin dye.

The third dye may be present in an amount from 0.001 wt % to 5 wt %, for example, from 0.1 wt % to 5 wt % or from 0.1 wt % to 2 wt %, relative to the transmittance control layer.

This way, the third dye can be configured to increase transmittance and reduce reflectance in combination with the other dyes in the transmittance control layer.

The fourth dye can have a maximum absorption wavelength from 650 nm to 700 nm and can be configured to reduce reflectance and improve screen quality.

The fourth dye may be a sulfonamide-substituted copper complex dye or the like. In an embodiment, the sulfonamide-substituted copper complex dye may include a dye represented by Formula 4:

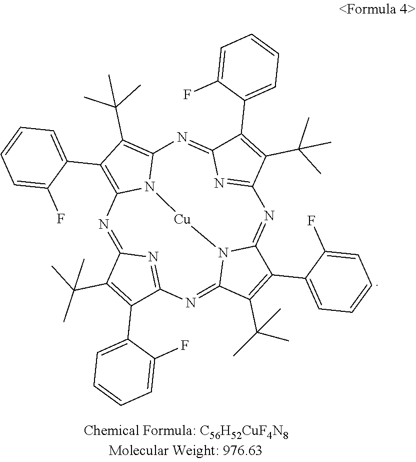

The fourth dye may be present in an amount from 0.001 wt % to 5 wt %, for example, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, 4, 4.1, 4.2, 4.3, 4.4, 4.5, 4.6, 4.7, 4.8, 4.9, 5 wt %, from 0.1 wt % to 5 wt % or from 0.1 wt % to 2 wt %, relative to the transmittance control layer. This way, the fourth dye can be configured to increase transmittance and reduce reflectance in combination with the other dyes in the transmittance control layer.

The mixture of the first dye, the second dye, the third dye, and the fourth dye mixture may be present in an amount from 3 wt % to 15 wt %, for example, 3, 4, 5, 6, 7, 8, 9, 10, 11, 12, 13, 14, 15 wt %, from 3 wt % to 10 wt %, relative to the transmittance control layer.

This way, the dye mixture can be configured to reduce reflectance and improve screen quality.

The dye mixture can degrade when exposed to UV light for an extended period of time under repeat temperature fluctuations between room temperature and elevated temperature.

The transmittance control layer can include a (meth)acrylic copolymer, wherein the (meth)acrylic copolymer can be a cycloaliphatic group-containing (meth)acrylic copolymer having a glass transition temperature from 50° C. to 150° C. As the (meth)acrylic copolymer has a glass transition temperature equal to or greater than 50° C., the (meth)acrylic copolymer can be configured to prevent degradation of the dye mixture while minimizing variations in luminance and reflectance. In addition, as the (meth)acrylic copolymer has a glass transition temperature equal to or less than 150° C., the (meth)acrylic copolymer can be configured to prevent degradation of the dye mixture while minimizing variations in luminance and reflectance.

In an embodiment, the (meth)acrylic copolymer can be a copolymer of a monomer mixture including a cycloaliphatic group-containing monomer, wherein the cycloaliphatic group-containing monomer may be present in an amount from 35 wt % to 70 wt %, for example, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70 wt %, from 40 wt % to 70 wt % or from 50 wt % to 60 wt %, relative to the monomer mixture. This way, the cycloaliphatic group-containing monomer can be configured to further enhance the effectiveness of the (meth)acrylic copolymer in protection of the dye mixture and minimize variations in luminance and reflectance.

The cycloaliphatic group-containing (meth)acrylic monomer may include a (meth)acrylic acid ester having a monocyclic or bicyclic C₅ to C₂₀ cycloaliphatic group. In an embodiment, the cycloaliphatic group-containing (meth)acrylic monomer may be a monofunctional monomer.

In an embodiment, the cycloaliphatic group-containing (meth)acrylic monomer may include one or more of cyclohexyl (meth)acrylate, isobornyl (meth)acrylate, dicyclopentanyl (meth)acrylate, methylcyclohexyl (meth)acrylate, and dicyclopentenyl (meth)acrylate.

The monomer mixture may further include a comonomer (or a second monomer), in addition to the cycloaliphatic group-containing (meth)acrylic monomer. The comonomer may have a homopolymer glass transition temperature equal to or greater than 50° C., for example, from 50° C. to 150° C. This way, the (meth)acrylic copolymer can be configured to meet the glass transition temperature requirements.

The comonomer may include any comonomer that has a homopolymer glass transition temperature equal to or greater than 50° C., for example, from 50° C. to 150° C., without limitation.

In an embodiment, the comonomer may include an alkyl group-containing (meth)acrylic monomer. In an embodiment, the alkyl group-containing (meth)acrylic monomer may include a (meth)acrylic acid ester having a C₁ to C₁₀ alkyl group. In an embodiment, the alkyl group-containing (meth)acrylic monomer may include methyl (meth)acrylate.

The comonomer may be present in an amount from 30 wt % to 65 wt %, for example, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60 wt %, from 30 wt % to 60 wt % or from 40 wt % to 50 wt %, relative to the monomer mixture. This way, the comonomer can be configured to form a matrix of the transmittance control layer.

In an embodiment, the cycloaliphatic group-containing (meth)acrylic monomer and the comonomer having a homopolymer glass transition temperature equal to or greater than 50° C., for example 50° C. to 150° C., may be present in a total amount equal to or greater than 95 wt %, for example, from 98 wt % to 100 wt % or 100 wt %, relative to the monomer mixture. This way, the transmittance control layer can be configured to achieve desired effects of the optical member.

The transmittance control layer may have a thickness equal to or less than 100 μm, for example, 1 μm to 50 μm. This way, the transmittance control layer can be used in an optical display apparatus.

### Base Film

The base film may be formed on the transmittance control layer and can be configured to protect the adhesive layer and the transmittance control layer and to enhance mechanical strength of the optical member. In an embodiment, the base film may be directly formed on the transmittance control layer. As used herein, the expression “directly formed” means that no other adhesive layer or bonding layer is interposed between the base film and the transmittance control layer.

In an embodiment, the base film may have a light transmittance equal to or greater than 80%, for example, from 90% to 99%. This way, the base film can be configured to enhance luminous efficacy by not negatively affecting an optical path of external light or internal light transmitted through the optical member.

In an embodiment, the base film may have a light transmittance equal to or less than 1%, for example, from 0.1% to 1%, at a wavelength of 380 nm.

The base film may include at least one of an optically clear protective film or an optically clear protective coating layer.

In an embodiment, the base film is of the protective film type. The base film may include a protective film formed of an optically clear resin. The protective film may be formed by melt extrusion of the resin. If necessary, the resin may be further subjected to a stretching process. The resin may include one or more of a cellulose ester resin, such as triacetyl cellulose, a cyclic polyolefin resin, such as an amorphous cyclic olefin polymer (COP), a polycarbonate resin, a polyester resin, such as polyethylene terephthalate (PET), a polyether sulfone resin, a polysulfone resin, a polyamide resin, a polyimide resin, an acyclic polyolefin resin, a poly(meth)acrylate resin, such as poly(methyl methacrylate), a polyvinyl alcohol resin, a polyvinyl chloride resin, and a polyvinylidene chloride resin.

In an embodiment, the base film is of the protective coating layer type. The base film can have good properties in terms of adhesion to the adhesive layer, transparency, mechanical strength, thermal stability, moisture barrier capacity, and durability. In an embodiment, the protective coating layer as the base film may be formed of an actinic radiation-curable resin composition including an actinic radiation-curable compound and a polymerization initiator.

The actinic radiation-curable compound may include one or more of a cationic polymerizable curable compound, a radical polymerizable curable compound, a urethane resin, and a silicone resin. The cationic polymerizable curable compound may be an epoxy compound having at least one epoxy group in a molecule thereof or an oxetane compound having at least one oxetane ring in a molecule thereof. The radical polymerizable curable compound may be a (meth)acrylic compound having at least one (meth)acryloyloxy group in a molecule thereof.

The base film may have a thickness from 5 μm to 200 μm, for example, from 30 μm to 120 μm or from 50 μm to 100 μm (in the case of the protective film type), or from 5 μm to 50 μm (in the case of the protective coating layer type). This way, the base film can be used in an optical display apparatus.

The optical member may be in the absence of a functional coating layer, such as an antireflection layer, on one or more surfaces of the base film.

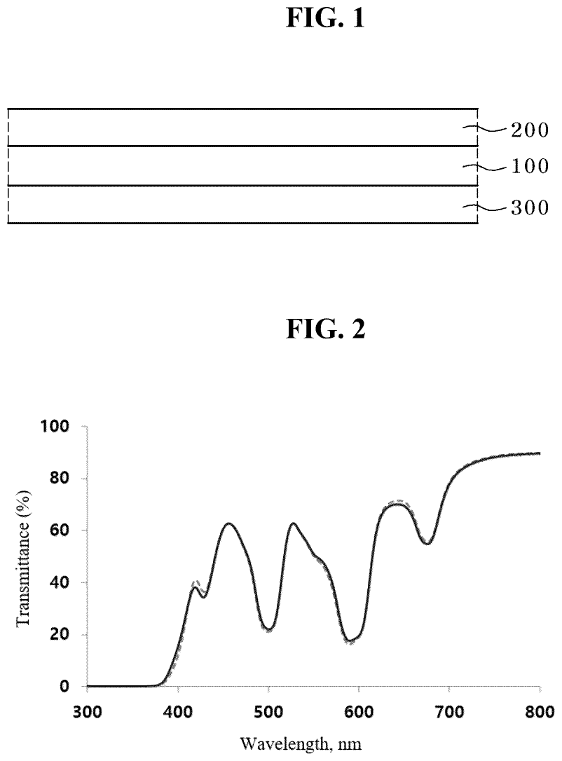

FIG. 1 is a cross-sectional view of an optical member, according to an embodiment of the present disclosure.

Referring to FIG. 1, the optical member includes: an adhesive layer 300; and a transmittance control layer 100 and a base film 200 sequentially formed on an upper surface of the adhesive layer 300. Although not shown in FIG. 1, the optical member may further include a release film formed on a lower surface of the adhesive layer 300.

Embodiments of the present disclosure provide an optical display apparatus.

The optical display apparatus can include the optical member.

In an embodiment, the optical display apparatus may include a panel for the optical display apparatus and the optical member can be stacked on the panel.

In an embodiment, the optical display is in the absence of a polarizing plate. With the optical member capable of replacing the function of a polarizing plate, the optical display apparatus can be configured to prevent damage to a light emitting device, even without a polarizing plate.

The optical display apparatus may include a liquid crystal display apparatus, a light emitting display apparatus, such as an organic light emitting display apparatus, and the like, without being limited thereto.

ExamplesThe present disclosure includes description in more detail with reference to certain examples. However, it should be noted that these examples are provided for illustration only and are not to be construed in any way as limiting.

### Preparative Example 1: Preparation of (Meth)Acrylic Copolymer

First, 50 g of toluene was placed in a 500 mL reactor provided with a reflux condenser for temperature control and a nitrogen gas inlet. Thereafter, 100 parts by weight of a monomer mixture including monomers listed in Table 1 in amounts listed in Table 1 was added to the reactor. Thereafter, nitrogen gas was introduced to the reactor for 30 minutes to purge oxygen from the reactor removing any residual oxygen from the monomer mixture, followed by maintaining the internal temperature of the reactor at 70° C. After the monomer mixture was thoroughly stirred, 0.06 parts by weight of V601 (dimethyl 2,2′-azobis(2-methylpropionate)) as an initiator and a chain extender were added to the reactor and the internal temperature of the reactor was increased to 75° C., and was maintained for 4 hours. After maintaining the internal temperature at 75° C. for an additional 2 hours, the reactor was cooled to room temperature, and toluene was added to the reactor, thereby preparing a solution containing 35 wt % of a (meth)acrylic copolymer. The weight average molecular weight and glass transition temperature of the prepared (meth)acrylic copolymer were obtained by gel permeation chromatography (GPC) and differential scanning calorimetry (DSC) analyses.

### Preparative Examples 2 to 6 and 8: Preparation of (Meth)Acrylic Copolymer

(Meth)acrylic copolymers were prepared in the same manner as in Preparative Example 1 except that the type and content of each monomer in the monomer mixture were changed as listed in Table 1 and the content of the initiator or reaction time was changed. In Table 1, “−” means that the content of a corresponding component is 0 mol %.

### Preparative Example 7: IF850 NP was Used as a (Meth)Acrylic Copolymer

TABLE 1

| Preparative | | | | | | | |
|---|---|---|---|---|---|---|---|
| Example | MMA | MA | CHA | IBXA | DCPA | Mw | Tg |
| 1 | 50 | — | 50 | — | — | 165,550 | 53.8 |
| 2 | 50 | — | — | 50 | — | 177,276 | 112.4 |
| 3 | 50 | — | — | — | 50 | 190,092 | 95.9 |
| 4 | 40 | — | 60 | — | — | 158,500 | 52.1 |
| 5 | 100 | — | — | — | — | 166,561 | 105 |
| 6 | 46 | 54 | — | — | — | 199,436 | 45.6 |
| 7 | 100 | — | — | — | — | 87,021 | 105 |
| 8 | 80 | — | 20 | — | | 187,551 | 84 |

*In Table 1,
MMA: Methyl methacrylate (homopolyer Tg: 105° C., Sigma-Aldrich Chemical Co., Inc.)
MA: Methyl acrylate (homopolymer Tg: 8° C., Sigma-Aldrich Chemical Co., Inc.)
CHA: Cyclohexyl acrylate (homopolyer Tg: 19° C., TCI Co., Ltd.)
IBXA: Isobornyl acrylate (homopolymer Tg: 94° C., Sigma-Aldrich Chemical Co., Inc.)
DCPA: Dicyclopentanyl acrylate (homopolymer Tg: 120° C., TCI Co., Ltd.)
Details of components used in Examples and Comparative Examples are as follows.
(A) (Meth)acrylic copolymer: The (meth)acrylic copolymers prepared in Preparative Examples 1 to 8 (see Table 1).
(B) Dye
(B1) VP-40 (maximum absorption wavelength: 431 nm, dialkoxy grroup-substituted porphyrin (Cu²⁺ complex) dye, synthesized, represented by formula below) 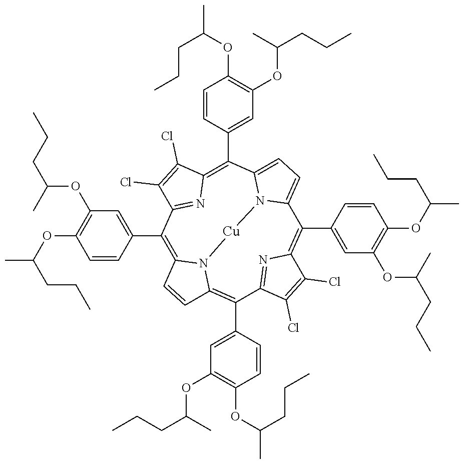
(B2) FDB-022 (maximum absorption wavelength: 493 nm, non-disclosed structure, Yamada chemical Co., Ltd.)
(B3) CD30 (maximum absorption wavelength: 506 nm, py-EWG-substituted BODIPY dye, synthesized, represented by formula below) 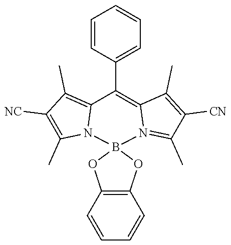
(B4) FDG-004 (maximum absorption wavelength: 576 nm, non-disclosed structure, Yamada chemical Co., Ltd.)
(B5) AMC 581 (maximum absorption wavelength: 581 nm, non-disclosed structure, AMC Corp.)
(B6) KIS-001 (maximum absorption wavelength: 593 nm, tetraazaporphyrin dye, Kyungin Synthetic Co., Ltd.)
(B7) FDR-001 (maximum absorption wavelength: 604 nm, non-disclosed structure, Yamada chemical Co., Ltd.)
(B8) RP-Cu-01 (maximum absorption wavelength: 676 nm, sulfonamide-substituted PC dye, synthesized, represented by formula below)

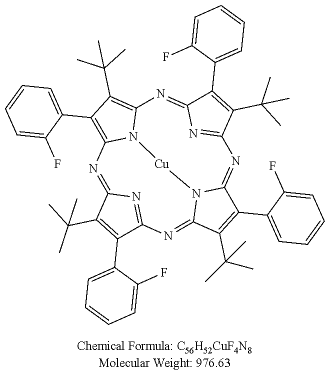

### Example 1

The (meth)acrylic copolymer prepared in Preparative Example 1 was dissolved at a concentration of 35 wt % in toluene. Each of dyes (B1) to (B8) was dissolved at a concentration of 1 wt % to 5 wt % in methyl ethyl ketone or toluene. The resulting solutions were mixed in amounts listed in Table 3 in terms of solid content, thereby preparing a transmittance control layer composition.

The prepared transmittance control layer composition was applied at a predetermined thickness to a lower surface of a base film (triacetyl cellulose, thickness: 40 μm, PG402S, Hyosung Chemical Co., Ltd.), followed by drying at 120° C. for 2 minutes, thereby forming a transmittance control layer (thickness: 2.3 μm) on the lower surface of the base film.

An acrylic copolymer (free from carboxylic acid groups, CI-247, SOKEN Chemical Co., Ltd.) was mixed with a UV absorber (UA-3912, Orient Chemical Co., Ltd.), an isocyanate curing agent (TD-75, SOKEN Chemical Co., Ltd.), a crosslinking catalyst (Sn catalyst (DBTDL)), an adhesion enhancer (CK-500), and a silane coupling agent (A-50), followed by stirring with a mechanical stirrer for 20 minutes. Thereafter, the resulting mixture was degassed for 40 minutes, thereby preparing an adhesive layer composition. The content of each component in the adhesive layer composition is shown in Table 2.

TABLE 2

| Component | Content (g) |
|---|---|
| CI-247 | 87.056 |
| TD-75 | 0.091 |
| Sn Catalyst | 0.003 |
| A-50 | 0.22 |
| CK-500 | 12 |
| UA-3912 | 0.63 |

The prepared adhesive layer composition was applied at a predetermined thickness to one surface of a release film (thickness: 38 μm), dried at 100° C. for 4 minutes, covered with a triacetyl cellulose film (thickness: 50 μm), and aged at 35° C. and 45% RH for 2 days, thereby manufacturing a stack of the release film/an adhesive layer (thickness: 15 μm)/the triacetyl cellulose film.

Thereafter, only the adhesive layer was attached to a lower surface of the transmittance control layer, thereby manufacturing an optical member.

### Examples 2 to 4

Optical members were manufactured in the same manner as in Example 1 except that the type of (meth)acrylic copolymer in the transmittance control layer composition was changed as listed in Table 3.

### Comparative Examples 1 to 4

Optical members were manufactured in the same manner as in Example 1 except that the type of (meth)acrylic copolymer in the transmittance control layer composition was changed as listed in Table 3.

Each of the optical members manufactured in Examples 1 to 4 and Comparative Examples 1 to 4 was evaluated as to the properties listed in Table 3 and Table 4. Results are shown in Table 3, Table 4, FIG. 2, and FIG. 3.

### (1) Color Coordinates of Optical Member

Using a light transmittance measuring instrument (V-650 UV-spectrometer, JASCO Corp.), brightness L, color value a*, and color value b* of each of the optical members manufactured in Examples 1 to 4 and Comparative Examples 1 to 4 under a D65 light source were determined from a transmittance spectrum of the optical member.

### (2) Reflectance of Optical Member

After each of the optical members manufactured in Examples 1 to 4 and Comparative Examples 1 to 4 was attached to a mobile OLED panel using the adhesive layer of the optical member, reflectance was measured in a reflection mode and in an SCI mode using a spectrophotometer (CM-3600a, Konica Minolta Inc.).

### (3) Estimated Luminous Efficacy

Luminous efficacy of a panel was estimated using a film transmittance spectrum measured for each of the optical members manufactured in Examples 1 to 4 and Comparative Examples 1 to 4. A luminance ratio of the optical member to a polarizing film was calculated under the assumption that a typical polarizing film has a transmittance of 50%.

P(λ): OLED spectrum, y(λ): Spectrum of each of the optical members manufactured in Examples 1 to 4 and Comparative Examples 1 to 4

$$Estimated luminous efficacy = ( A / B ) * 100$$

$$A = {\int }_{450}^{470} P ( λ ) \times y ( λ ) d λ + {\int }_{520}^{550} P ( λ ) \times y ( λ ) d λ + {\int }_{610}^{637} P ( λ ) \times y ( λ ) d λ$$

$$B = ( {\int }_{450}^{470} P ( λ ) d λ + {\int }_{520}^{550} P ( λ ) d λ + {\int }_{610}^{637} P ( λ ) 0 \text{.5} d λ ) \times \frac{1}{2}$$

### (4) Initial Light Transmittance of Optical Member

Each of the optical members manufactured in Examples 1 to 4 and Comparative Examples 1 to 4 was cut to a size of 25 mm×200 mm (width×length) and attached to a glass plate, thereby preparing a specimen. Light transmittance of the specimen was measured in the wavelength range of 300 nm to 800 nm using a light transmittance measuring instrument (V-650 UV-spectrometer, JASCO Corp.). Light transmittances at 400 nm, 490 nm, and 585 nm were obtained from the measurement results.

### (5) Solar Test

Each of the optical members manufactured in Examples 1 to 4 and Comparative Examples 1 to 4 was cut to a size of 25 mm×200 mm (width×length) and attached to a glass plate, thereby preparing a specimen. The prepared specimen was placed in a UV chamber and irradiated with 340 nm UV light under the following conditions: Solar test conditions: A total of 21 cycles of light irradiation (252 hours in total), wherein one cycle was defined as irradiating the specimen with 340 nm UV light at a fluence of 0.35 W/m² while leaving the specimen at 25° C. for 4 hours and at 63° C. for 8 hours.

Thereafter, the specimen was removed from the UV chamber and then left at room temperature for 30 minutes, followed by obtaining light transmittances at 400 nm, 490 nm, and 585 nm in the same manner as in (4). A difference in light transmittance ΔT of the specimen before and after the solar test was calculated.

TABLE 3

| | | | Example 1 | Example 2 | Example 3 | Example 4 |
|---|---|---|---|---|---|---|
| Type of (meth)acrylic copolymer | | | Preparative | Preparative | Preparative | Preparative |
| | | | Example 1 | Example 2 | Example 3 | Example 4 |
| Content of (meth)acrylic copolymer | | | 91.60 | 91.60 | 91.60 | 91.60 |
| VP-40 | | | 1.12 | 1.12 | 1.12 | 1.12 |
| FDB-022 | | | 0.65 | 0.65 | 0.65 | 0.65 |
| CD30 | | | 1.02 | 1.02 | 1.02 | 1.02 |
| FDG-004 | | | 1.38 | 1.38 | 1.38 | 1.38 |
| AMC 581 | | | 0.93 | 0.93 | 0.93 | 0.93 |
| KIS-001 | | | 0.93 | 0.93 | 0.93 | 0.93 |
| FDR-001 | | | 1.25 | 1.25 | 1.25 | 1.25 |
| RP-Cu-01 | | | 1.12 | 1.12 | 1.12 | 1.12 |
| Thickness of transmittance | | | 2.3 | 2.4 | 2.1 | 2.4 |
| control layer (μm) | | | | | | |
| Color | L | | 68.4 | 67.04 | 67.1 | 67.1 |
| coordinates | a* | | 0.53 | 0.57 | 0.55 | 0.55 |
| | b* | | −5.75 | −5.8 | −5.79 | −5.79 |
| Reflectance (%) | | | 7.07 | 6.79 | 7.73 | 6.81 |
| Estimated luminous efficacy (%) | | | 134 | 133 | 137 | 133 |
| Light | 0 hr | @400 nm | 17.50 | 17.05 | 18.69 | 17.05 |
| transmittance | | @490 nm | 16.80 | 16.25 | 22.98 | 16.25 |
| (%) | | @585 nm | 12.39 | 12.03 | 17.37 | 12.03 |
| | 250 hr | @400 nm | 20.20 | 19.55 | 21.43 | 19.55 |
| | | @490 nm | 19.40 | 18.92 | 25.31 | 18.92 |
| | | @585 nm | 14.85 | 14.18 | 19.85 | 14.18 |
| | ΔT | @400 nm | 2.70 | 2.50 | 2.75 | 2.50 |
| | | @490 nm | 2.60 | 2.67 | 2.33 | 2.67 |
| | | @585 nm | 2.46 | 2.15 | 2.48 | 2.15 |

TABLE 4

| | | | Comparative | Comparative | Comparative | Comparative |
|---|---|---|---|---|---|---|
| | | | Example 1 | Example 2 | Example 3 | Example 4 |
| Type of (meth)acrylic copolymer | | | Preparative | Preparative | Preparative | Preparative |
| | | | Example 5 | Example 6 | Example 6 | Example 7 |
| Content of (meth)acrylic copolymer | | | 91.60 | 91.60 | 91.60 | 91.60 |
| VP-40 | | | 1.12 | 1.12 | 1.12 | 1.12 |
| FDB-022 | | | 0.65 | 0.65 | 0.65 | 0.65 |
| CD30 | | | 1.02 | 1.02 | 1.02 | 1.02 |
| FDG-004 | | | 1.38 | 1.38 | 1.38 | 1.38 |
| AMC 581 | | | 0.93 | 0.93 | 0.93 | 0.93 |
| KIS-001 | | | 0.93 | 0.93 | 0.93 | 0.93 |
| FDR-001 | | | 1.25 | 1.25 | 1.25 | 1.25 |
| RP-Cu-01 | | | 1.12 | 1.12 | 1.12 | 1.12 |
| Thickness of transmittance | | | 2.3 | 2.2 | 2.5 | 2.5 |
| control layer (μm) | | | | | | |
| Color | L | | 69.04 | 69.58 | 66.21 | 66.4 |
| coordinates | a* | | 0.49 | 0.51 | 0.57 | 0.56 |
| | b* | | −5.67 | −5.6 | −5.82 | −5.81 |
| Reflectance (%) | | | 7.20 | 7.32 | 6.63 | 6.67 |
| Estimated luminous efficacy (%) | | | 134 | 135 | 132 | 132 |
| Light | 0 hr | @400 nm | 18.09 | 20.07 | 16.47 | 16.61 |
| transmittance | | @490 nm | 18.33 | 20.92 | 15.89 | 16.01 |
| (%) | | @585 nm | 13.93 | 14.89 | 10.66 | 11.02 |
| | 250 hr | @400 nm | 20.78 | 22.79 | 19.13 | 19.25 |
| | | @490 nm | 30.36 | 28.06 | 28.33 | 24.51 |
| | | @585 nm | 17.19 | 18.61 | 14.46 | 14.25 |
| | ΔT | @400 nm | 2.69 | 2.72 | 2.66 | 2.64 |
| | | @490 nm | 12.03 | 7.13 | 12.45 | 8.50 |
| | | @585 nm | 3.26 | 3.72 | 3.80 | 3.23 |

As can be seen in Table 3, the optical members according to the present disclosure exhibited a reflectance of 6.5% to 9.5%, as measured on a panel, and had a minimallight transmittance variation at a wavelength from 400 nm to 600 nm after long-term exposure to UV light under repeat temperature fluctuations between room temperature and elevated temperature.

Conversely, as can be seen in Table 4, the optical members of Comparative Examples 1 to 4 exhibited a reflectance of 6.5% to 9.5%, as measured on a panel, but had a relatively greater light transmittance variation over the wavelength from 400 nm to 600 nm, after long-term exposure to UV light under repeat temperature fluctuations between room temperature and elevated temperature, than the optical members of Examples 1 to 4. Particularly, the optical members of Comparative Examples 1 to 4 exhibited a light transmittance variation of greater than 3% at wavelengths from 490 nm and 585 nm after long-term exposure to UV light, under repeat temperature fluctuations between room temperature and high temperature.

It should be understood that various modifications, changes, alterations, and equivalent embodiments can be made by those skilled in the art without departing from the spirit of the present disclosure.

What is claimed is:

1. An optical member comprising:
an adhesive layer;
a transmittance control layer formed on an upper surface of the adhesive layer, the transmittance control layer comprising a (meth)acrylic copolymer and a dye mixture, the dye mixture comprising a first dye having a maximum absorption wavelength from 400 nm to 440 nm, a second dye having a maximum absorption wavelength from 480 nm to 520 nm, a third dye having a maximum absorption wavelength from 570 nm to 610 nm, and a fourth dye having a maximum absorption wavelength from 650 to 700 nm; and
a base film formed on an upper surface of the transmittance control layer,
wherein the (meth)acrylic copolymer comprises a cycloaliphatic group-containing (meth)acrylic copolymer having a glass transition temperature from 50° C. to 150° C., and
wherein the cycloaliphatic group-containing (meth)acrylic copolymer comprises from 35 wt % to 70 wt % of a cycloaliphatic group-containing (meth)acrylic monomer.

2. The optical member as claimed in claim 1, wherein the cycloaliphatic group-containing (meth)acrylic monomer comprises a (meth)acrylic acid ester having a monocyclic or bicyclic C₅ to C₂₀ cycloaliphatic group.

3. The optical member as claimed in claim 1, wherein the cycloaliphatic group-containing (meth)acrylic monomer comprises at least one of cyclohexyl (meth)acrylate, isobornyl (meth)acrylate, dicyclopentanyl (meth)acrylate, methylcyclohexyl (meth)acrylate, or dicyclopentenyl (meth)acrylate.

4. The optical member as claimed in claim 1, wherein the cycloaliphatic group-containing (meth)acrylic copolymer further comprises a second monomer having a homopolymer glass transition temperature of equal to or greater than 50° C.

5. The optical member as claimed in claim 4, wherein the second monomer comprises an alkyl group-containing (meth)acrylic monomer.

6. The optical member as claimed in claim 4, wherein the cycloaliphatic group-containing (meth)acrylic copolymer comprises equal to or greater than 95 wt % of collectively the cycloaliphatic group-containing (meth)acrylic monomer and the second monomer.

7. The optical member as claimed in claim 1, wherein the first dye is a dialkoxy group-substituted porphyrin dye.

8. The optical member as claimed in claim 1, wherein the first dye comprises a dye represented by Formula 2:

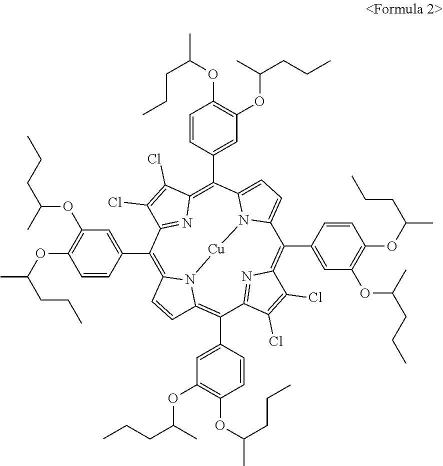

9. The optical member as claimed in claim 1, wherein the second dye comprises a BODIPY dye.

10. The optical member as claimed in claim 9, wherein the BODIPY dye comprises a dye represented by Formula 3:

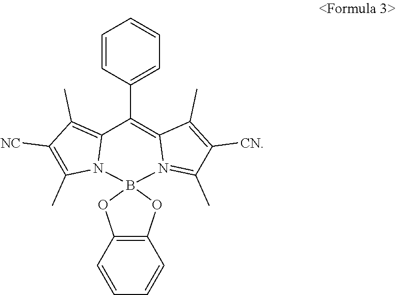

11. The optical member as claimed in claim 1, wherein the third dye comprises a tetraazaporphyrin dye.

12. The optical member as claimed in claim 1, wherein the fourth dye comprises a sulfonamide-substituted copper complex dye.

13. The optical member as claimed in claim 12, wherein the sulfonamide-substituted copper complex dye comprises a dye represented by Formula 4:

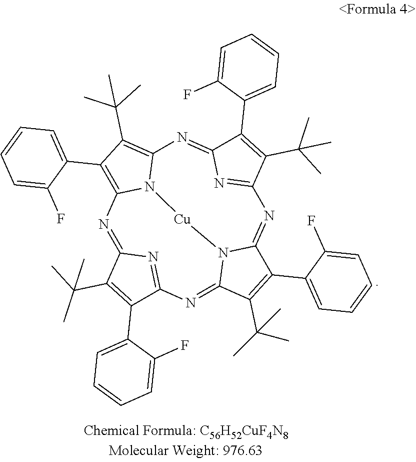

14. The optical member as claimed in claim 1, wherein the dye mixture comprises:
from 0.001 wt % to 5 wt % of the first dye;
from 0.001 wt % to 5 wt % of the second dye;
from 0.001 wt % to 5 wt % of the third dye; and
from 0.001 wt % to 5 wt % of the fourth dye.

15. The optical member as claimed in claim 1, wherein the base film is in an absence of an antireflection layer.

16. The optical member as claimed in claim 1, wherein the adhesive layer comprises a UV absorber.

17. An optical display apparatus comprising the optical member as claimed in claim 1.

18. The optical display apparatus as claimed in claim 17, wherein the optical display apparatus is in an absence of a polarizing plate.
